(19) United States
(12) Patent Application Publication
(10) Pub. No.: US 2024/0396299 A1
(43) Pub. Date: Nov. 28, 2024

(54) Semiconductor Laser

(71) Applicant: Nippon Telegraph and Telephone Corporation, Tokyo (JP)

(72) Inventors: Takuma Aihara, Musashino-shi, Tokyo (JP); Shinji Matsuo, Musashino-shi, Tokyo (JP); Suguru Yamaoka, Musashino-shi, Tokyo (JP); Tatsuro Hiraki, Musashino-shi, Tokyo (JP)

(21) Appl. No.: 18/561,147

(22) PCT Filed: Jun. 24, 2021
(86) PCT No.: PCT/JP2021/023908

§ 371 Date: Nov. 15, 2023

(51) Int. Cl. H01S 5/12

(52) U.S. Cl. CPC H01S 5/1215

(57) ABSTRACT

A semiconductor laser is a DFB laser including an active layer formed in a core shape extending in a waveguide direction on a substrate and including a diffraction grating in a resonator, and includes a first region and a second region in which a stop band is modulated in the resonator. The first region and the second region are arranged with an interval therebetween in the waveguide direction. The first region and the second region modulate the stop band by changing the pitch of the diffraction grating.

### TECHNICAL FIELD

The present invention relates to a semiconductor laser.

### BACKGROUND ART

With an increase in communication traffic on the Internet or the like, high speed and large capacity information transmission is required. In particular, in a data center, a direct modulation laser that is small in size, low in cost, low in power consumption, and capable of high speed modulation is required.

In order to increase the capacity in the future, it is desired to further increase the speed of the laser, to perform wavelength multiplexing using a plurality of lasers, and to reduce the power consumption at the same time. In response to this demand, a thin film lateral direction injection type laser capable of wavelength multiplexing and having low power consumption is expected (Non Patent Literature 1).

Use of photon-photon resonance (PPR) is useful for increasing the speed of the laser. PPR is a technique of expanding a modulation band by providing a light feedback mechanism in a laser, and the modulation band is expanded for the following reasons.

For example, a structure in which a Fabry-Perot resonator is added to a distributed feedback (DFB) laser is considered. The light emitted from the laser is reflected from the Fabry-Perot resonator, and the light is fed back to the laser. When the phase of the feedback light is in phase with the phase of the emitted light, the optical power in the laser is intensified, and the optical power is enhanced resonantly. When the modulation frequency of the laser matches the resonance frequency of the Fabry-Perot resonator, the modulation degree increases at the modulation frequency. Therefore, it is possible to directly expand the modulation band of the modulation laser by appropriately adjusting the resonance frequency and the phase. Actually, as described in Non Patent Literature 2, high speed direct modulation is realized by using PPR.

### CITATION LIST

### Non Patent Literature

Non Patent Literature 1: S. Matsuo et al., “Directly modulated buried heterostructure DFB laser on SiO2/Si substrate fabricated by regrowth of InP using bonded active layer”, Optics Express, vol. 22, no. 10, pp. 12139-12147, 2014.
Non Patent Literature 2: S. Yamaoka et al., “Directly modulated membrane lasers with 108 GHz bandwidth on a high-thermal-conductivity silicon carbide substrate”, Nature Photonics, vol. 15, pp. 28-35, 2021.

### SUMMARY OF INVENTION

### Technical Problem

However, in the above-described technique, it is necessary to make the phases of the light emitted from the laser and the feedback light in-phase, and for this purpose, a specific current injection condition of the laser or a phase adjustment mechanism (for example, a heater) of the Fabry-Perot resonator is required.

Since the former changes in response to a change in the operation environment temperature, it is necessary to change the injection conditions according to the environment temperature in applications where the environment temperature is severe, the control becomes complicated, and it becomes difficult to stably use PPR. Similarly, the latter also has a problem that control becomes complicated and it is difficult to stably use PPR, and in addition, power consumption in the heater is added such that power consumption as a whole increases. As described above, the conventional technique has a problem that it is not easy to use photon-photon resonance.

The present invention has been made to solve the above problems, and an object thereof is to make it possible to easily use photon-photon resonance.

### Solution to Problem

According to the present invention, there is provided a semiconductor laser, in which a diffraction grating is provided in a resonator, including: a first cladding layer formed on a substrate; an active layer formed in a core shape extending in a waveguide direction on the first cladding layer; a p-type semiconductor layer and an n-type semiconductor layer formed in contact with the active layer with the active layer interposed therebetween; a second cladding layer formed on the active layer; and a p-electrode and an n-electrode connected to the p-type semiconductor layer and the n-type semiconductor layer, in which a first region and a second region having a different pitch of the diffraction grating in the waveguide direction are provided in the resonator, and the first region and the second region are arranged with an interval therebetween in the waveguide direction.

In addition, according to the present invention, there is provided a semiconductor laser, in which a diffraction grating is provided in a resonator, including: a first cladding layer formed on a substrate; an active layer formed in a core shape extending in a waveguide direction on the first cladding layer; a p-type semiconductor layer and an n-type semiconductor layer formed in contact with the active layer with the active layer interposed therebetween; a second cladding layer formed on the active layer; a p-electrode and an n-electrode connected to the p-type semiconductor layer and the n-type semiconductor layer; and an optical coupling layer embedded in the first cladding layer or the second cladding layer in a state of being able to be optically coupled with the active layer and formed in a core shape extending along the active layer, in which a first region and a second region having a different width of the optical coupling layer in a direction perpendicular to the waveguide direction are provided in the resonator, and the first region and the second region are arranged with an interval therebetween in the waveguide direction.

### Advantageous Effects of Invention

As described above, according to the present invention, since the first region and the second region in which the stop band is modulated are provided in the resonator by, for example, changing the pitch of the diffraction grating, the photon-photon resonance can be easily used in a distributed feedback laser or the like.

### BRIEF DESCRIPTION OF DRAWINGS

FIG. 1A is a sectional view illustrating a configuration of a semiconductor laser according to Embodiment 1 of the present invention.

FIG. 1B is a plan view illustrating a partial configuration of the semiconductor laser according to Embodiment 1 of the present invention.

FIG. 2 is an explanatory view for describing a diffraction grating 110 of the semiconductor laser according to Embodiment 1 of the present invention.

FIG. 3 is a band diagram illustrating a state where a stop band wavelength in a resonator is modulated by modulation of the diffraction grating 110.

FIG. 4 is a characteristics diagram illustrating a calculation result of an oscillation spectrum of a DFB laser having the stop band illustrated in FIG. 3.

FIG. 5A is a characteristics diagram illustrating a calculation result of Δλ using w2 and a gap in FIG. 3 as parameters.

FIG. 5B is a characteristics diagram illustrating a calculation result of a threshold value gain difference Δgth using w2 and a gap in FIG. 3 as parameters.

FIG. 6 is a sectional view illustrating a configuration of another semiconductor laser according to Embodiment 1 of the present invention.

FIG. 7A is a sectional view illustrating a configuration of a semiconductor laser according to Embodiment 2 of the present invention.

FIG. 7B is a plan view illustrating a partial configuration of the semiconductor laser according to Embodiment 2 of the present invention.

FIG. 8A is a sectional view illustrating a configuration of a semiconductor laser according to Embodiment 3 of the present invention.

FIG. 8B is a plan view illustrating a partial configuration of the semiconductor laser according to Embodiment 3 of the present invention.

FIG. 8C is a plan view illustrating a partial configuration of the semiconductor laser according to Embodiment 3 of the present invention.

### DESCRIPTION OF EMBODIMENTS

Hereinafter, a semiconductor laser according to an embodiment of the present invention will be described.

### Embodiment 1

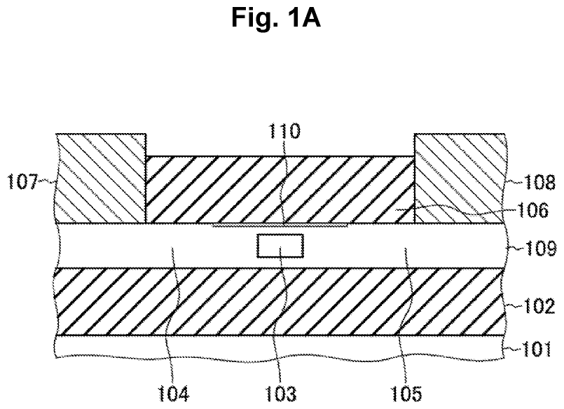

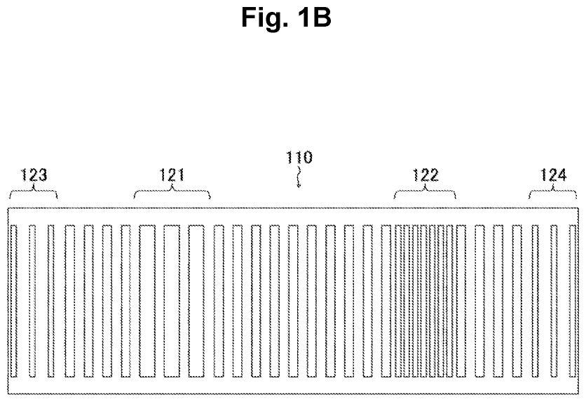

First, a semiconductor laser according to Embodiment 1 of the present invention is described with reference to FIGS. 1A and 1B. This semiconductor laser is a distributed feedback (DFB) laser including an active layer 103 formed in a core shape extending in a waveguide direction on a substrate 101 and including a diffraction grating 110 in a resonator.

In this semiconductor laser, first, a first cladding layer 102 is formed on a substrate 101, and an active layer 103 is provided on the first cladding layer 102. The substrate 101 is made of, for example, Si, and the first cladding layer 102 is made of, for example, silicon oxide. In addition, a p-type semiconductor layer 104 and an n-type semiconductor layer 105 formed in contact with the active layer 103 with the active layer 103 interposed therebetween are provided. In addition, a second cladding layer 106 formed on the active layer 103, and a p-electrode 107 and an n-electrode 108 connected to the p-type semiconductor layer 104 and the n-type semiconductor layer 105 are provided.

In this example, the p-type semiconductor layer 104 and the n-type semiconductor layer 105 are formed by introducing impurities into the semiconductor layer 109 made of InP, for example. In addition, between the p-type semiconductor layer 104 and the n-type semiconductor layer 105, the active layer 103 is formed by being embedded in the semiconductor layer 109. For example, the diffraction grating 110 can be formed at an interface between the semiconductor layer 109 and the second cladding layer 106.

In addition to the above-described configuration, as illustrated in FIG. 1B, the semiconductor laser according to Embodiment 1 includes a first region 121 and a second region 122 in which the stop band is modulated in the resonator. The first region 121 and the second region 122 are arranged with an interval therebetween in the waveguide direction. The first region 121 and the second region 122 modulate the stop band by changing the pitch of the diffraction grating 110.

The first region 121 and the second region 122 are different from other regions in the pitch of the diffraction grating 110 in the waveguide direction. In addition, the pitch of the diffraction grating 110 in the first region 121 is made larger than that in the other regions, and the pitch of the diffraction grating 110 in the second region 122 is made smaller than that in the other regions. For example, the pitch of the diffraction grating 110 in the first region 121 can be twice the pitch of the diffraction grating 110 in the second region 122. Note that FIG. 1B is a plan view illustrating a configuration of the diffraction grating 110, and a direction from right to left in the drawing of FIG. 1B is a waveguide direction.

In this example, the third region 123 and the fourth region 124 in which the stop band is modulated are provided at both ends in the resonator. The third region 123 and the fourth region 124 modulate the stop band by changing the duty ratio of the diffraction grating 110. The duty ratio of the diffraction grating 110 in the waveguide direction of the third region 123 on one end side and the fourth region 124 on another end side in the resonator is smaller than the duty ratio of the region inside the third region 123 and the fourth region 124.

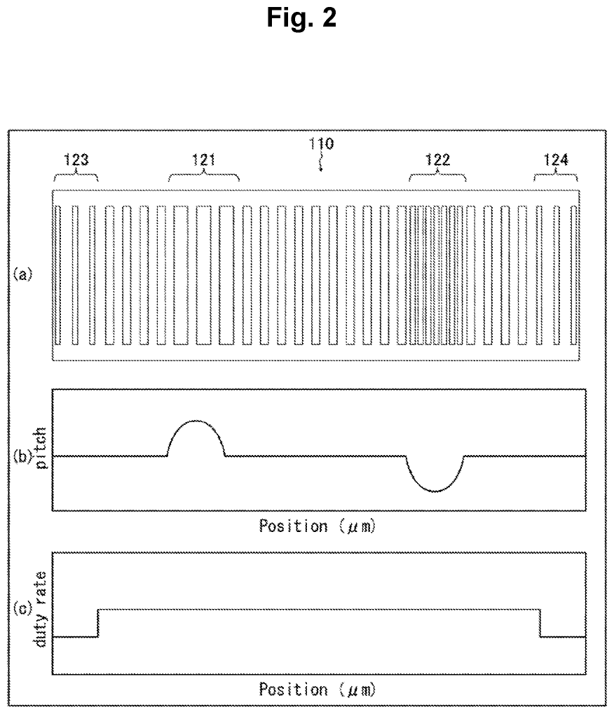

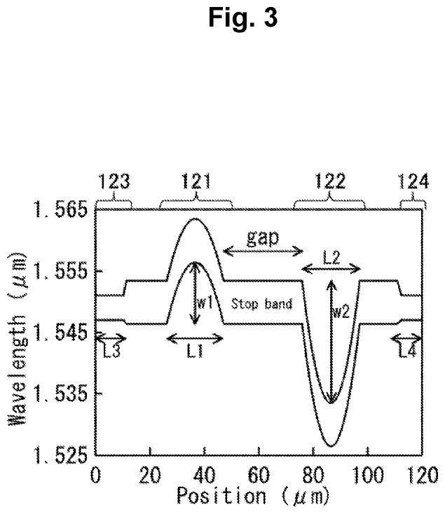

The pitch and duty ratio of the diffraction grating 110 are modulated as illustrated in FIG. 2. By the modulation of the diffraction grating 110, the stop band wavelength in the resonator is modulated into the form illustrated in FIG. 3. For example, the stop band wavelength of the first region 121 in which the pitch of the diffraction grating 110 is increased shifts to the longer wavelength side. In addition, the third region 123 and the fourth region 124 where the duty ratio of the diffraction grating 110 is decreased have a narrow stop band width.

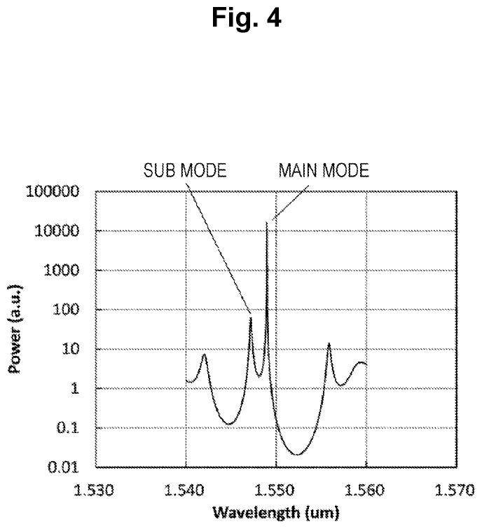

FIG. 4 illustrates a calculation result of the oscillation spectrum of the DFB laser having the stop band as illustrated in FIG. 3. As illustrated in FIG. 4, the sub mode appears in the main mode and the wavelength adjacent thereto. Here, a wavelength difference between the main mode and the sub mode is Δλ. Basically, the DFB laser oscillates at the wavelength of the main mode. When the laser is directly modulated, when the modulation frequency of the laser matches Δλ, the main mode and the sub mode are intensified in the resonator, and the optical power is resonantly enhanced, and thus the modulation degree increases at the modulation frequency that matches Δλ.

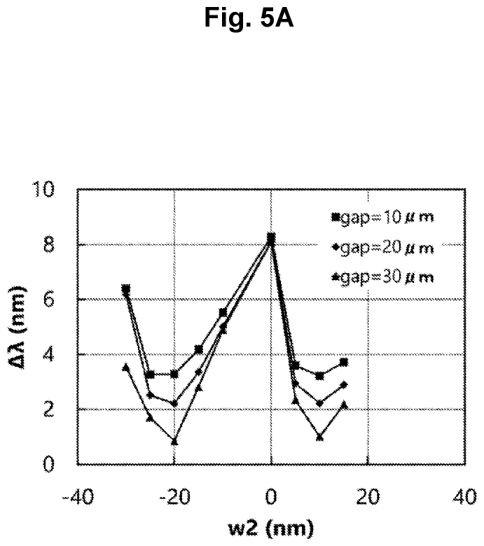

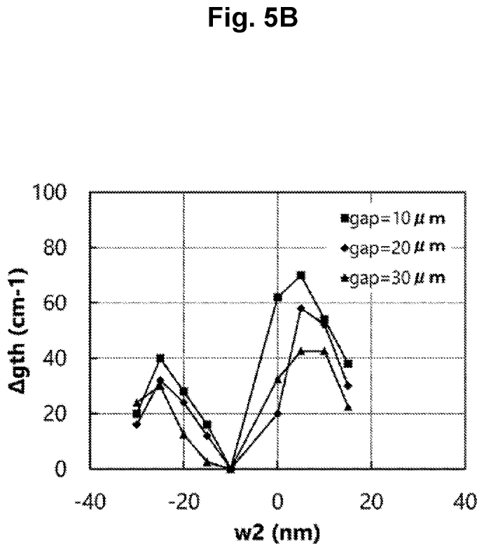

The value of Δλ can be adjusted by w2 and a gap in FIG. 3. A calculation result of Δλ using w2 and a gap as parameters is illustrated in FIG. 5A. As illustrated in FIG. 5A, when w2 is set to approximately −20 nm (the sign of w1 is inverted and approximately 2 times), it can be found that Δλ decreases. In addition, it can be found that Δλ decreases as the gap increases. In particular, when w2=−20 nm and gap=30 μm, it can be found that approximately Δλ=0.8 nm (Δf=100 GHz). This means that, as modulation band characteristics, a modulation degree is improved by photon-photon resonance (PPR) in the vicinity of a modulation frequency of 100 GHz.

In addition, it is necessary to provide a threshold value gain difference between the main mode and the sub mode in order to prevent multimode oscillation. As illustrated in FIG. 5B, in the vicinity of w2=−20 nm, there is a threshold value gain difference Δgth of approximately 30 cm⁻¹, which is a value sufficient for single mode oscillation.

In the above structure, PPR can be expressed without requiring an external resonator separately from the DFB laser. Therefore, it is not necessary to match the phases of the light emitted from the DFB laser and the feedback light. As a result, according to Embodiment 1, since PPR is expressed even under no specific current injection condition of the DFB laser, high speed direct modulation is realized regardless of the operation environment. In addition, according to Embodiment 1, since a phase adjustment mechanism (for example, a heater) is not required, it is effective for reducing power consumption.

Note that modulation regions of the first region 121 and the second region 122, and the third region 123 and the fourth region 124 of the diffraction grating 110 are modulated by a smooth function. This is because a rapid change in pitch or duty ratio increases scattering loss. Examples of the modulation function include a parabolic function, a Gaussian function, and a Lorentz function.

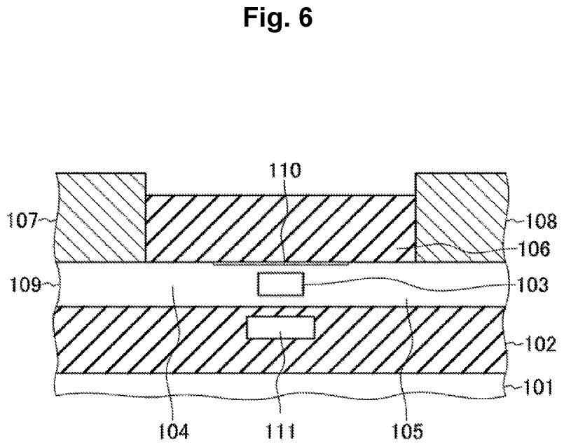

As illustrated in FIG. 6, it is possible to further include an optical coupling layer 111 that is embedded in the first cladding layer 102 in a state of being optically couplable with the active layer 103, and is formed in a core shape extending along the active layer 103. The optical coupling layer 111 may be made of, for example, a single crystal silicon.

### Embodiment 2

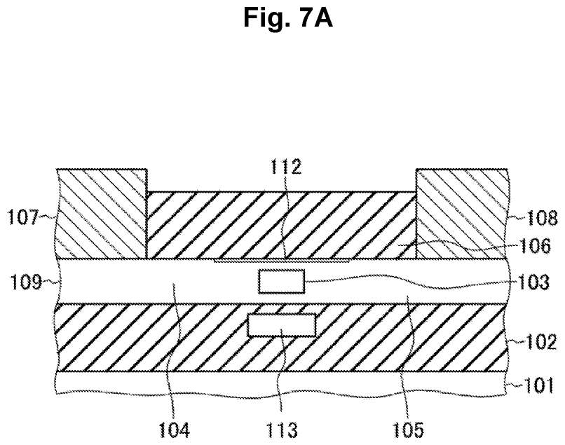

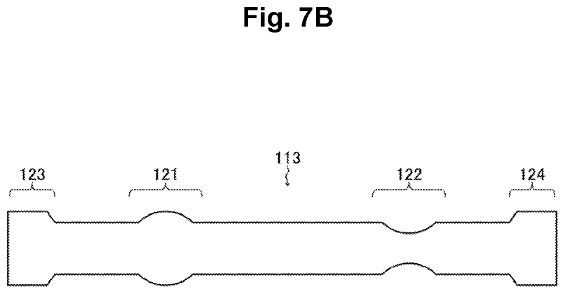

Next, a semiconductor laser according to Embodiment 2 of the present invention is described with reference to FIGS. 7A and 7B. This semiconductor laser is a DFB laser including the active layer 103 formed in a core shape extending in the waveguide direction on the substrate 101 and including a diffraction grating 112 in the resonator.

In this semiconductor laser, first, a first cladding layer 102 is formed on a substrate 101, and an active layer 103 is provided on the first cladding layer 102. The substrate 101 is made of, for example, Si, and the first cladding layer 102 is made of, for example, silicon oxide. In addition, a p-type semiconductor layer 104 and an n-type semiconductor layer 105 formed in contact with the active layer 103 with the active layer 103 interposed therebetween are provided. In addition, a second cladding layer 106 formed on the active layer 103, and a p-electrode 107 and an n-electrode 108 connected to the p-type semiconductor layer 104 and the n-type semiconductor layer 105 are provided.

In this example, the p-type semiconductor layer 104 and the n-type semiconductor layer 105 are formed by introducing impurities into the semiconductor layer 109 made of InP, for example. In addition, between the p-type semiconductor layer 104 and the n-type semiconductor layer 105, the active layer 103 is formed by being embedded in the semiconductor layer 109. In addition, an optical coupling layer 113 that is embedded in the first cladding layer 102 in a state of being optically couplable with the active layer 103, and is formed in a core shape extending along the active layer 103 is included. The optical coupling layer 113 may be made of, for example, a single crystal silicon.

In addition to the above-described configuration, as illustrated in FIG. 7B, the semiconductor laser according to the embodiment includes the first region 121 and the second region 122 in which the stop band is modulated in the resonator. The first region 121 and the second region 122 are arranged with an interval therebetween in the waveguide direction. The first region 121 and the second region 122 modulate the stop band by changing the width of the optical coupling layer 113.

The first region 121 and the second region 122 are different from other regions in the width of the optical coupling layer 113 in the waveguide direction. In addition, the width of the optical coupling layer 113 in the first region 121 is made larger than that in the other regions, and the width of the optical coupling layer 113 in the second region 122 is made smaller than that in the other regions. Note that FIG. 7B is a plan view illustrating a configuration of the optical coupling layer 113, and a direction from right to left in the drawing of FIG. 7B is a waveguide direction.

In this example, the third region 123 and the fourth region 124 in which the stop band is modulated are provided at both ends in the resonator. The third region 123 and the fourth region 124 also modulate the stop band by changing the width of the optical coupling layer 113. The width of the optical coupling layer 113 in the waveguide direction of the third region 123 on one end side and the fourth region 124 on another end side in the resonator is larger than the width of the region inside the third region 123 and the fourth region 124.

As described above, by providing the optical coupling layer 113 and further changing the width of the optical coupling layer 113 in the first region 121, the second region 122, the third region 123, and the fourth region 124, the stop band wavelength in the resonator is modulated as illustrated in FIG. 3. By changing the width of the optical coupling layer 113, the coupling coefficient of the diffraction grating 112 and the ratio of optical confinement in the active layer 103 can be changed, and as described above, the stop band wavelength in the resonator can be modulated.

As described above, also in Embodiment 2, since the stop band wavelength in the resonator can be modulated, similarly to Embodiment 1 described above, PPR can be expressed without using an external resonator separately from the DFB laser. Therefore, it is not necessary to match the phases of the light emitted from the DFB laser and the feedback light. As a result, according to Embodiment 2, since PPR is expressed even under no specific current injection condition of the DFB laser, high speed direct modulation is realized regardless of the operation environment. In addition, according to Embodiment 2, since a phase adjustment mechanism, for example, a heater, is not required, it is effective for reducing power consumption.

### Embodiment 3

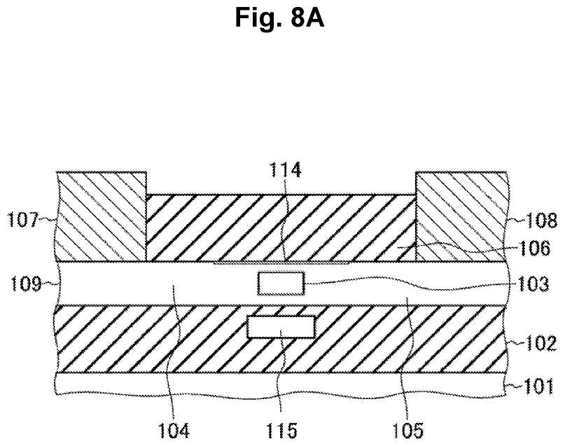

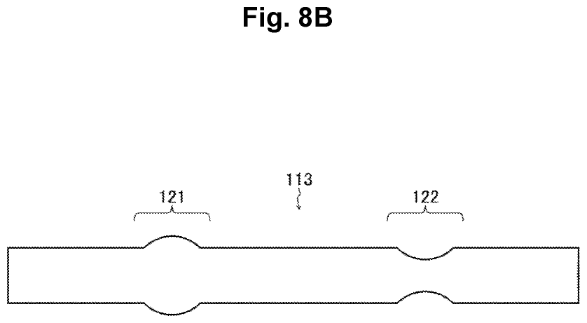

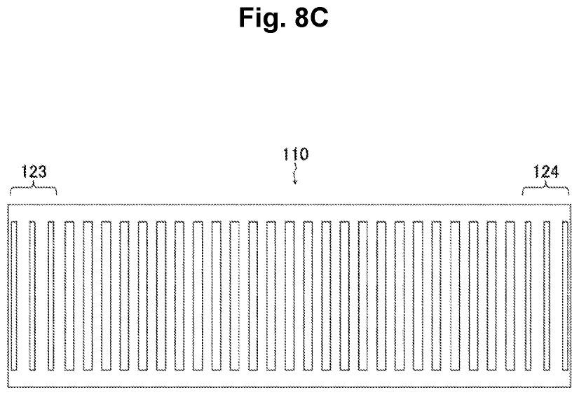

Next, a semiconductor laser according to Embodiment 3 of the present invention is described with reference to FIGS. 8A, 8B, and 8C. This semiconductor laser is a DFB laser including the active layer 103 formed in a core shape extending in the waveguide direction on the substrate 101 and including a diffraction grating 114 in the resonator.

In this semiconductor laser, first, a first cladding layer 102 is formed on a substrate 101, and an active layer 103 is provided on the first cladding layer 102. The substrate 101 is made of, for example, Si, and the first cladding layer 102 is made of, for example, silicon oxide. In addition, a p-type semiconductor layer 104 and an n-type semiconductor layer 105 formed in contact with the active layer 103 with the active layer 103 interposed therebetween are provided. In addition, a second cladding layer 106 formed on the active layer 103, and a p-electrode 107 and an n-electrode 108 connected to the p-type semiconductor layer 104 and the n-type semiconductor layer 105 are provided.

In this example, the p-type semiconductor layer 104 and the n-type semiconductor layer 105 are formed by introducing impurities into the semiconductor layer 109 made of InP, for example. In addition, between the p-type semiconductor layer 104 and the n-type semiconductor layer 105, the active layer 103 is formed by being embedded in the semiconductor layer 109. In addition, an optical coupling layer 113 that is embedded in the first cladding layer 102 in a state of being optically couplable with the active layer 103, and is formed in a core shape extending along the active layer 103 is included. The optical coupling layer 113 may be made of, for example, a single crystal silicon.

In addition to the above-described configuration, as illustrated in FIG. 8B, the semiconductor laser according to the embodiment includes the first region 121 and the second region 122 in which the stop band is modulated in the resonator. The first region 121 and the second region 122 are arranged with an interval therebetween in the waveguide direction. The first region 121 and the second region 122 modulate the stop band by changing the width of the optical coupling layer 113.

The first region 121 and the second region 122 are different from other regions in the width of the optical coupling layer 113 in the waveguide direction. In addition, the width of the optical coupling layer 113 in the first region 121 is made larger than that in the other regions, and the width of the optical coupling layer 113 in the second region 122 is made smaller than that in the other regions. Note that FIG. 8B is a plan view illustrating a configuration of the optical coupling layer 113, and a direction from right to left in the drawing of FIG. 8B is a waveguide direction.

In Embodiment 3, as illustrated in FIG. 8C, the third region 123 and the fourth region 124 in which the stop band is modulated are provided at both ends in the resonator. The third region 123 and the fourth region 124 modulate the stop band by changing the duty ratio of the diffraction grating 114. The duty ratio of the diffraction grating 114 in the waveguide direction of the third region 123 on one end side and the fourth region 124 on another end side in the resonator is smaller than the duty ratio of the region inside the third region 123 and the fourth region 124.

As described above, by providing the first region 121, the second region 122, the third region 123, and the fourth region 124, the stop band wavelengths of the first region 121, the second region 122, the third region 123, and the fourth region 124 in the resonator are modulated as illustrated in FIG. 3.

As described above, also in Embodiment 3, since the stop band wavelength in the resonator can be modulated, similarly to Embodiment 1 described above, PPR can be expressed without using an external resonator separately from the DFB laser. Therefore, it is not necessary to match the phases of the light emitted from the DFB laser and the feedback light. As a result, according to Embodiment 3, since PPR is expressed even under no specific current injection condition of the DFB laser, high speed direct modulation is realized regardless of the operation environment. In addition, according to Embodiment 3, since a phase adjustment mechanism, for example, a heater, is not required, it is effective for reducing power consumption.

As described above, according to the present invention, since the first region and the second region in which the stop band is modulated are provided in the resonator by, for example, changing the pitch of the diffraction grating, the photon-photon resonance can be easily used in a distributed feedback laser or the like.

Note that the present invention is not limited to the embodiments described above, and it is obvious that many modifications and combinations can be made by those skilled in the art within the technical idea of the present invention.

### REFERENCE SIGNS LIST

101 Substrate
102 First cladding layer
103 Active layer
104 p-type semiconductor layer
105 n-type semiconductor layer
106 Second cladding layer
107 p-electrode
108 n-electrode
109 Semiconductor layer
110 Diffraction grating

1. A semiconductor laser, in which a diffraction grating is provided in a resonator, comprising:
a first cladding layer formed on a substrate;
an active layer formed in a core shape extending in a waveguide direction on the first cladding layer;
a p-type semiconductor layer and an n-type semiconductor layer formed in contact with the active layer with the active layer interposed therebetween;
a second cladding layer formed on the active layer; and
a p-electrode and an n-electrode connected to the p-type semiconductor layer and the n-type semiconductor layer,
wherein
a first region and a second region in which a pitch of the diffraction grating in the waveguide direction is different from that of other regions are provided in the resonator,
the first region and the second region are arranged with an interval therebetween in the waveguide direction,
a pitch of the diffraction grating in the first region is made larger than that in the other region, and
a pitch of the diffraction grating in the second region is made smaller than that in the other region.

2. The semiconductor laser according to claim 1, wherein the pitch of the diffraction grating in the first region is twice the pitch of the diffraction grating in the second region.

3. The semiconductor laser according to claim 1, wherein a duty ratio of the diffraction grating in the waveguide direction of a third region on one end side and a fourth region on another end side in the resonator is smaller than a duty ratio of a region inside the third region and the fourth region.

4. A semiconductor laser, in which a diffraction grating is provided in a resonator, comprising:
a first cladding layer formed on a substrate;
an active layer formed in a core shape extending in a waveguide direction on the first cladding layer;
a p-type semiconductor layer and an n-type semiconductor layer formed in contact with the active layer with the active layer interposed therebetween;
a second cladding layer formed on the active layer;
a p-electrode and an n-electrode connected to the p-type semiconductor layer and the n-type semiconductor layer; and
an optical coupling layer embedded in the first cladding layer or the second cladding layer in a state of being able to be optically coupled with the active layer and formed in a core shape extending along the active layer and,
wherein
a first region and a second region in which a width of the optical coupling layer in a direction perpendicular to the waveguide direction is different from that of other regions are provided in the resonator,
the first region and the second region are arranged with an interval therebetween in the waveguide direction,
a width of the optical coupling layer in the first region is made larger than that in the other region, and
a width of the optical coupling layer in the second region is made smaller than that in the other region.

5. The semiconductor laser according to claim 4, wherein a width of the optical coupling layer in the third region on one end side and the fourth region on another end side in the resonator is larger than that in other regions.

6. The semiconductor laser according to claim 4, wherein the duty ratio of the diffraction grating in the waveguide direction of the third region on one end side and the fourth region on another end side in the resonator is smaller than the duty ratio of the region inside the third region and the fourth region.

7. The semiconductor laser according to claim 2, wherein a duty ratio of the diffraction grating in the waveguide direction of a third region on one end side and a fourth region on another end side in the resonator is smaller than a duty ratio of a region inside the third region and the fourth region.
